(19) United States
(12) Patent Application Publication
(10) Pub. No.: US 2017/0154868 A1
(43) Pub. Date: Jun. 1, 2017

(54) SEMICONDUCTOR PACKAGES

(71) Applicant: SK hynix Inc., Icheon-si (KR)

(72) Inventor: Seung Hee JO, Yongin-si (KR)

(21) Appl. No.: 15/096,749

(22) Filed: Apr. 12, 2016

(30) Foreign Application Priority Data
Dec. 1, 2015 (KR) 10-2015-0169696

(51) Int. Cl. H01L 25/065

(52) U.S. Cl. CPC H01L 25/0652; H01L 2225/06513; H01L 2225/06544; H01L 2225/06562; H01L 2225/06582

(57) ABSTRACT

A semiconductor package includes a first die including first chip pads disposed in a first chip pad region, first connecting pads spaced apart from the first chip pad region a predetermined distance and gathered in a first connecting pad region, and first redistribution layer patterns connecting the first chip pads to the first connecting pads, a second die including second chip pads disposed in a second chip pad region on the chip, second connecting pads spaced apart from the second chip pad region a predetermined distance and disposed in a second connecting pad region, and second redistribution layer patterns connecting the second chip pads to the second connecting pads, and a first semiconductor chip disposed below the first die and the second die, and electrically connected to the first connecting pads and the second connecting pads. The second connecting pad region is disposed adjacent to the first connecting pad region.

### CROSS-REFERENCE TO RELATED APPLICATION

The present application claims priority under 35 U.S.C §119(a) to Korean Patent Application No. 10-2015-0169696, filed on Dec. 1, 2015, which is herein incorporated by reference in its entirety.

### BACKGROUND

1. Technical Field

Various embodiments of the present disclosure relate to a packaging technology and, more particularly, to semiconductor packages capable of implementing a System In Package.

2. Related Art

Recently, as electronic products have become scaled down with high performance and portable mobile products are increasingly in demand, demands for compact and large capacity semiconductor memory devices have continuously increased. One technique for increasing the storage capacity of a semiconductor memory device is a System In Package (SIP) technique. In the SIP technique, a number of multi-functional electronic devices are integrated in a substrate and different kinds of semiconductor chips fabricated by different processes can be implemented as a single package. According to the SIP technique, there is an advantage in that the electronic products can be made smaller and lighter than when each of the semiconductor packages is disposed on a system substrate.

However, when the number and size of the chip(s) to be mounted in the semiconductor package increases, a lack of space for electrical interconnections within the semiconductor package has become a problem. To overcome this problem, a package structure using a through silicon via (TSV) has been suggested. According to a packaging technique using TSVs, TSVs are formed in each chip in a wafer process step, and electrical connections among the chips are formed using the TSVs. There is an advantage in using TSVs because a number of chips can be stacked in the vertical direction in a package, thereby enabling the development of a high capacity package. However, as the technique of mounting a plurality of memory chips using the TSVs increases the cost of a manufacturing process, studies on how to improve this are under way.

### SUMMARY

Various embodiments are directed to semiconductor packages having through silicon vias and methods for manufacturing the semiconductor packages.

According to an embodiment, a semiconductor package includes a first die including first chip pads disposed in a first chip pad region on a chip, first connecting pads disposed in a first connecting pad region located at a corner portion of the first die and spaced apart from the first chip pad region by a predetermined distance, and first redistribution layer patterns connecting the first chip pads to the first connecting pads, a second die including second chip pads disposed in a second chip pad region on the chip and spaced apart from the first die in a horizontal direction, second connecting pads disposed in a second connecting pad region located at a corner portion of the second die and spaced apart from the second chip pad region by a predetermined distance, and second redistribution layer patterns connecting the second chip pads to the second connecting pads, the second connecting pad region is disposed to be adjacent to the connecting pad region of the first die in the horizontal direction, a third die including third chip pads disposed in a third chip pad region on the chip and spaced apart from the second die by a predetermined distance in the horizontal direction, third connecting pads disposed in a third connecting pad region located at a corner portion of the third die and spaced apart from the third chip pad region by a predetermined distance, and third redistribution layer patterns connecting the third chip pads to the third connecting pads, the third connecting pad region is disposed to face the first connecting pad region of the first die in the diagonal direction, a fourth die including fourth chip pads disposed in a fourth chip pad region on the chip and spaced apart from the third die by a predetermined distance in the horizontal direction, fourth connecting pads disposed in a fourth connecting pad region located at a corner portion of the fourth die and spaced apart from the fourth chip pad region by a predetermined distance, and fourth redistribution layer patterns connecting the fourth chip pads to the fourth connecting pads, the fourth connecting pad region is disposed to face the second connecting pad region of the second die in the diagonal direction, and a first semiconductor chip disposed below the first to fourth dies and electrically connected to the first to fourth dies at a portion overlapped with the first to fourth connecting pad regions, respectively.

According to an embodiment, a semiconductor package includes a first die including first chip pads disposed in a first chip pad region on a chip, first connecting pads spaced apart from the first chip pad region by a predetermined distance and gathered in a first connecting pad region located at a corner portion of the first die, and first redistribution layer patterns connecting the first chip pads to the first connecting pads, a second die including second chip pads disposed in a second chip pad region on the chip, second connecting pads spaced apart from the second chip pad region by a predetermined distance and disposed in a second connecting pad region located at a corner portion of the second die, and second redistribution layer patterns connecting the second chip pads to the second connecting pads, the second connecting pad region is disposed at a position adjacent to the first connecting pad region, and a first semiconductor chip disposed below the first die and the second die, and electrically connected to the first connecting pads and the second connecting pads.

According to an embodiment, there is provided an electronic system including a memory card and a controller coupled to the memory card via a bus. The memory card or the controller includes a first die including first chip pads disposed in a first chip pad region on a chip, first connecting pads disposed in a first connecting pad region located at a corner portion of the first die and spaced apart from the first chip pad region by a predetermined distance, and first redistribution layer patterns connecting the first chip pads to the first connecting pads, a second die including second chip pads disposed in a second chip pad region on the chip and spaced apart from the first die in a horizontal direction, second connecting pads disposed in a second connecting pad region located at a corner portion of the second die and spaced apart from the second chip pad region by a predetermined distance, and second redistribution layer patterns connecting the second chip pads to the second connecting pads, the second connecting pad region is disposed to be adjacent to the connecting pad region of the first die in the horizontal direction, a third die including third chip pads disposed in a third chip pad region on the chip and spaced apart from the second die by a predetermined distance in the horizontal direction, third connecting pads disposed in a third connecting pad region located at a corner portion of the third die and spaced apart from the third chip pad region by a predetermined distance, and third redistribution layer patterns connecting the third chip pads to the third connecting pads, the third connecting pad region is disposed to face the first connecting pad region of the first die in the diagonal direction, a fourth die including fourth chip pads disposed in a fourth chip pad region on the chip and spaced apart from the third die by a predetermined distance in the horizontal direction, fourth connecting pads disposed in a fourth connecting pad region located at a corner portion of the fourth die and spaced apart from the fourth chip pad region by a predetermined distance, and fourth redistribution layer patterns connecting the fourth chip pads to the fourth connecting pads, the fourth connecting pad region is disposed to face the second connecting pad region of the second die in the diagonal direction, and a first semiconductor chip disposed below the first to fourth dies and electrically connected to the first to fourth dies at a portion overlapped with the first to fourth connecting pad regions, respectively.

According to an embodiment, there is provided an electronic system including a memory card and a controller coupled to the memory card via a bus. The memory card or the controller includes a first die including first chip pads disposed in a first chip pad region on a chip, first connecting pads spaced apart from the first chip pad region by a predetermined distance and gathered in a first connecting pad region located at a corner portion of the first die, and first redistribution layer patterns connecting the first chip pads to the first connecting pads, a second die including second chip pads disposed in a second chip pad region on the chip, second connecting pads spaced apart from the second chip pad region by a predetermined distance and disposed in a second connecting pad region located at a corner portion of the second die, and second redistribution layer patterns connecting the second chip pads to the second connecting pads, the second connecting pad region is disposed at a position adjacent to the first connecting pad region, and a first semiconductor chip disposed below the first die and the second die, and electrically connected to the first connecting pads and the second connecting pads.

According to an embodiment, there is provided a memory card including a memory component and a memory controller that controls operations of the memory. The memory component includes a first die including first chip pads disposed in a first chip pad region on a chip, first connecting pads disposed in a first connecting pad region located at a corner portion of the first die and spaced apart from the first chip pad region by a predetermined distance, and first redistribution layer patterns connecting the first chip pads to the first connecting pads, a second die including second chip pads disposed in a second chip pad region on the chip and spaced apart from the first die in a horizontal direction, second connecting pads disposed in a second connecting pad region located at a corner portion of the second die and spaced apart from the second chip pad region by a predetermined distance, and second redistribution layer patterns connecting the second chip pads to the second connecting pads, the second connecting pad region is disposed to be adjacent to the connecting pad region of the first die in the horizontal direction, a third die including third chip pads disposed in a third chip pad region on the chip and spaced apart from the second die by a predetermined distance in the horizontal direction, third connecting pads disposed in a third connecting pad region located at a corner portion of the third die and spaced apart from the third chip pad region by a predetermined distance, and third redistribution layer patterns connecting the third chip pads to the third connecting pads, the third connecting pad region is disposed to face the first connecting pad region of the first die in the diagonal direction, a fourth die including fourth chip pads disposed in a fourth chip pad region on the chip and spaced apart from the third die by a predetermined distance in the horizontal direction, fourth connecting pads disposed in a fourth connecting pad region located at a corner portion of the fourth die and spaced apart from the fourth chip pad region by a predetermined distance, and fourth redistribution layer patterns connecting the fourth chip pads to the fourth connecting pads, the fourth connecting pad region is disposed to face the second connecting pad region of the second die in the diagonal direction, and a first semiconductor chip disposed below the first to fourth dies and electrically connected to the first to fourth dies at a portion overlapped with the first to fourth connecting pad regions, respectively.

According to an embodiment, there is provided a memory card including a memory component and a memory controller that controls operations of the memory. The memory component includes a first die including first chip pads disposed in a first chip pad region on a chip, first connecting pads spaced apart from the first chip pad region by a predetermined distance and gathered in a first connecting pad region located at a corner portion of the first die, and first redistribution layer patterns connecting the first chip pads to the first connecting pads, a second die including second chip pads disposed in a second chip pad region on the chip, second connecting pads spaced apart from the second chip pad region by a predetermined distance and disposed in a second connecting pad region located at a corner portion of the second die, and second redistribution layer patterns connecting the second chip pads to the second connecting pads, the second connecting pad region is disposed at a position adjacent to the first connecting pad region, and a first semiconductor chip disposed below the first die and the second die, and electrically connected to the first connecting pads and the second connecting pads.

### BRIEF DESCRIPTION OF THE DRAWINGS

Various embodiments of a present disclosure will become more apparent in view of the attached drawings and accompanying detailed description, in which:

FIG. 1 is a perspective view illustrating a semiconductor package according to an embodiment;

FIG. 2 is a plan view illustrating the semiconductor package of FIG. 1;

FIGS. 3 and 4 are cross-sectional views illustrating the semiconductor package taken along A-A′ and B-B′ directions in FIG. 2, respectively;

FIG. 5 is a plan view illustrating a semiconductor package according to another embodiment;

FIGS. 6 to 22 are views illustrating a method of manufacturing a semiconductor package according to an embodiment;

FIG. 23 is a block diagram illustrating an electronic system including a semiconductor device in accordance with an embodiment; and

FIG. 24 is a block diagram illustrating another electronic system including a semiconductor device in accordance with an embodiment.

### DETAILED DESCRIPTION OF THE EMBODIMENTS

In the following description of the embodiments, it will be understood that when an element is referred to as being located “on”, “over”, “above”, “under”, “beneath” or “below” another element, it may directly contact the other element, or at least one intervening element may be present therebetween. Accordingly, the terms such as “on”, “over”, “above”, “under”, “beneath”, “below” and the like that are used herein are for the purpose of describing particular embodiments only and are not intended to limit the scope of the present disclosure.

In the drawings, thicknesses and lengths of components are exaggerated as compared to actual physical thicknesses and intervals for convenience of illustration. In the following description, a detailed explanation of known related functions and constitutions may be omitted to avoid unnecessarily obscuring the subject manner. Furthermore, “connected/coupled” represents that one component is directly coupled to another component or indirectly coupled through another component. In this specification, a singular form may include a plural form as long as it is not specifically mentioned in a sentence. Furthermore, “include/comprise” or “including/comprising” used in the specification represents that one or more components, steps, operations, and elements exist or are added.

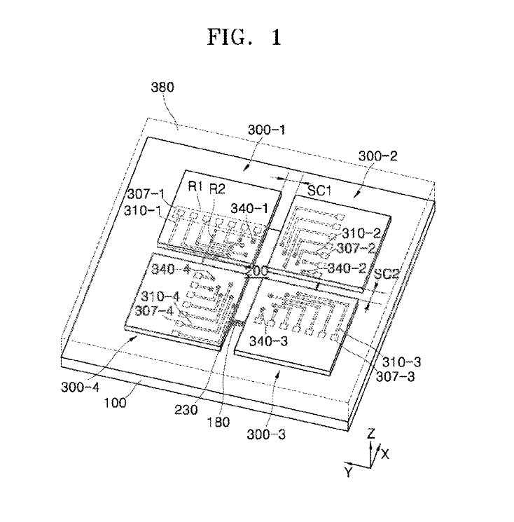

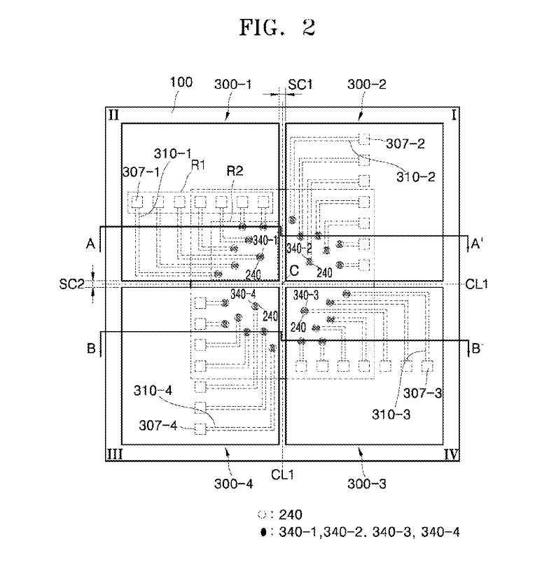

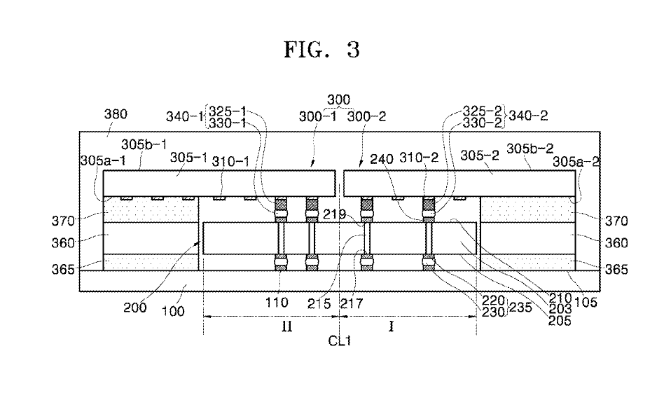

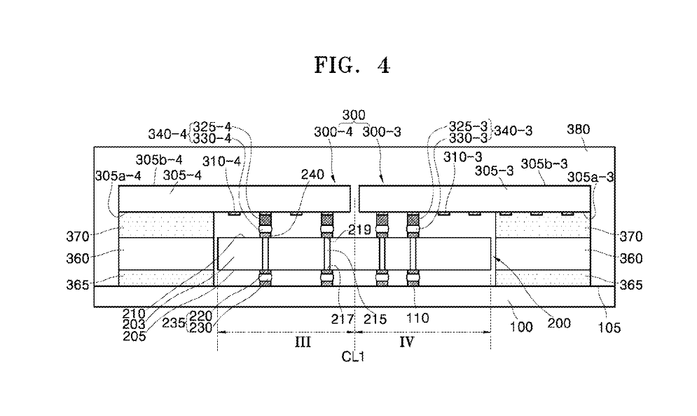

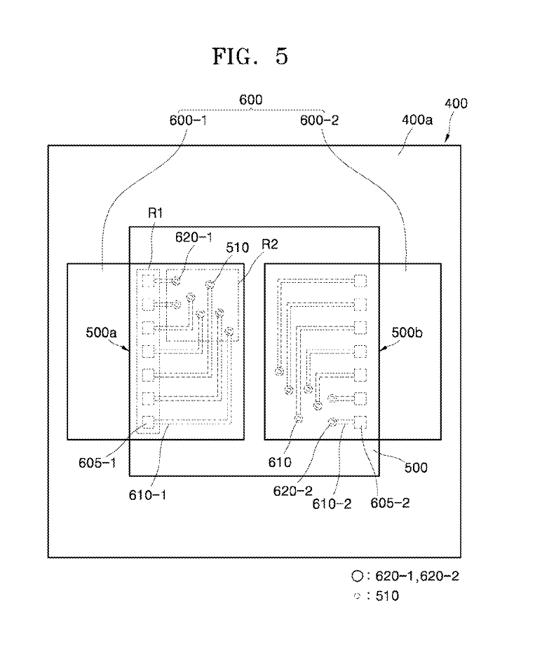

FIG. 1 is a perspective view illustrating a semiconductor package according to an embodiment. FIG. 2 is a plan view illustrating the semiconductor package of FIG. 1. FIGS. 3 and 4 are cross-sectional views illustrating the semiconductor package taken along A-A′ and B-B′ directions in FIG. 2, respectively.

Referring to FIGS. 1 to 4, the semiconductor package according to an embodiment includes a package substrate 100, a first semiconductor chip 200 disposed on the package substrate 100, at least one or more second semiconductor chips 300-1, 300-2, 300-3 and 300-4 disposed on the first semiconductor chip 200. The package substrate 100 may include a printed circuit board (PCB). A plurality of substrate pads 110 for electrically connecting the package substrate 100 to the first semiconductor chip 200 are disposed on a front-side 105 of the package substrate 100. Although it is not illustrated, circuit wiring patterns may be disposed in the package substrate 100. The substrate pads 110 may include a conductive material, such as copper (Cu), nickel (Ni) or gold (Au).

The first semiconductor chip 200 is disposed on the package substrate 100. The first semiconductor chip 200 includes a core portion 203 having a front-side 205 and a back-side 210 opposite to the front-side 205. The core portion 203 may include silicon (Si). In an embodiment, the term “front-side” refers a side on which semiconductor devices, such as active devices or passive devices, are to be formed, that is, the term refers to a side where an active region exists. The term “back-side” refers to a side opposite to the front-side. In an embodiment, the first semiconductor chip 200 may be a logic chip constituted as a system on chip (SOC). The SOC may include a microprocessor or a controller.

Through silicon vias (TSVs) 215 are formed in the core portion 203 of the first semiconductor chip 200. Each of the through silicon vias (TSVs) 215 may be formed of a metal filling a via hole penetrating the core portion 203 from the front-side 205 to the back-side 210. The metal forming the through silicon via (TSV) 215 may include copper (Cu), silver (Ag), or tin (Sn). Although it is not illustrated, a barrier layer preventing the metal from being diffused to the core portion 203 may be disposed in an inner side wall of the via hole.

The through silicon via (TSV) 215 includes a first end portion 217 adjacent to the front-side 205, and a second end portion 219 adjacent to the back-side 210. Each of the through silicon vias (TSVs) 215 are connected to a front-side bump 235 at the first end portion 217. The front-side bump 235 includes a metal pillar 220 and a solder bump 230 formed on the metal pillar 220. The metal pillar 220 may have a columnar shape and the solder bump 230 may have a hemispherical shape. The metal pillar 220 may include copper (Cu). Each of the through silicon vias (TSVs) 215 is connected to a back-side bump 240 at the second end portion 219 opposite to the first end portion 217. The back-side bump 240 may have a larger diameter than that of the through silicon via 215. Accordingly, a bottom surface of the back-side bump 240 may extend to partially cover a surface of the back-side 210 of the core portion 203. The back-side bump 240 may include copper (Cu). A top surface of the back-side bump 240 may be covered with nickel (Ni) or gold (Au).

The plurality of through silicon vias (TSVs) 215 are spaced apart from each other at a predetermined distance on the first semiconductor chip 200. As illustrated in FIG. 2, the first semiconductor chip 200 includes four sections I, II, III and IV which are divided by central lines CL1 intersecting the first semiconductor chip 200 in the horizontal and vertical directions. The divided sections include a first section I, a second section II, a third section III, and a fourth section IV, and each of the sections may have a square shape.

The through silicon vias (TSVs) 215 may be locally distributed in a certain area in each of the four sections I, II, III and IV of square shape. In an embodiment, the through silicon vias (TSVs) 215 may be exclusively distributed in an area adjacent to the central lines (CL1) dividing the four sections I, II, III and IV and close to the center (C) of the first semiconductor chip 200.

The through silicon vias (TSVs) 215 disposed in the first section I and connected to the back-side bump 240 are disposed at a location rotated by 90 degrees relative to the center (C) of the first semiconductor chip 200 from the through silicon vias 215 disposed in the second section II and connected to the back-side bump 240. Also, the through silicon vias 215 disposed in the fourth section IV are disposed at a location rotated by 90 degrees relative to the center (C) of the first semiconductor chip 200 from the through silicon vias 215 of the first section I, and rotated by 180 degrees from the through silicon vias 215 of the second section II. In addition, the through silicon vias 215 disposed in the third section III are disposed at a location rotated by 90 degrees relative to the center (C) of the first semiconductor chip 200 from the through silicon vias 215 of the fourth section IV, and rotated by 270 degrees from the through silicon vias 215 of the second section II. The first semiconductor chip 200 is attached to the substrate pads 110 of the package substrate 100 through the solder bumps 230 of the front-side bump 235.

The second semiconductor chips 300-1, 300-2, 300-3 and 300-4 are disposed in the four sections I, II, III and IV of the first semiconductor chip 200, respectively. The second semiconductor chips consist of a first die 300-1, a second die 300-2, a third die 300-3, and a fourth die 300-4. Each of the second semiconductor chips 300-1, 300-2, 300-3 and 300-4 may be a semiconductor memory chip requiring high integration and high capacity. For example, each of the second semiconductor chips 300-1, 300-2, 300-3 and 300-4 may be a memory chip in which memory integrated circuits, such as DRAM, SRAM, FLASH memory, MRAM, ReRAM, FeRAM, or PcRAM are integrated. The second semiconductor chips 300-1, 300-2, 300-3 and 300-4 disposed on the first semiconductor chip 200 may be memory chips which perform the same functions. In other words, the first semiconductor chip 200 may be disposed below and electrically connected to the first to fourth dies 300-1 to 300-4 at a location overlapping the first to fourth connecting pad regions (see for example, first connecting pad region R2), respectively. In addition, in an embodiment, the first to fourth dies 300-1 to 300-4 may have the substantially same structure, and may be disposed symmetrically to each other by 90 degree intervals relative to the center (C) of the first semiconductor chip 200. This will be described again later.

Referring to FIGS. 2 and 3, the first die 300-1 includes a substrate 305-1 having a first side 305a-1 and a second side 305b-1 opposite to the first side 305a-1, first chip pads 307-1, first connecting pads 340-1, and first redistribution layer (RDL) patterns 310-1 connecting the first chip pads 307-1 to the first connecting pads 340-1, respectively. The first side 305a-1 of the substrate 305-1 refers a side in which an active region exists. The first chip pads 307-1, the first connecting pads 340-1, and the first RDL patterns 310-1 are disposed on the first side 305a-1 of the substrate 305-1.

The first chip pads 307-1 are disposed in a first chip pad region R1 of the first side 350a-1 of the substrate 305-1. The adjacent first chip pads 307-1 are arranged in a line and spaced apart from each other a predetermined distance in the first chip pad region R1. Although, in this embodiment, it is illustrated that the first chip pad region R1 is disposed in a central portion of the first side 305a-1, it is not limited thereto. For example, though it is not illustrated, the first chip pad region R1 may be disposed at an edge portion of the first side 305a-1 of the substrate 305-1. The first chip pads 307-1 may include copper (Cu) or aluminum (Al).

A first connecting pad region R2 is disposed to be spaced apart from the first chip pad region R1 by a predetermined distance at one corner portion among corner portions of the first die 300-1. The first connecting pads 340-1 are distributed exclusively in the first connecting pad region R2. More specifically, the first connecting pads 340-1 may be disposed to be adjacent to the central line CL1 defining the four sections I, II, III and IV of the first semiconductor chip 200, and the first connecting pads 340-1 may be gathered in the center (C) portion of the first semiconductor chip 200. Each of the first connecting pads 340-1 includes a first metal bump 325-1 and a second metal bump 330-1 which are sequentially stacked. The first metal bump 325-1 may have a pillar shape including copper (Cu), and the second metal bump 330-1 may include a tin-silver (Sn—Ag) alloy.

The first RDL patterns 310-1 electrically connect the first chip pads 307-1 to the first connecting pads 340-1. Each of the first RDL patterns 310-1 contacts one side of each of the first chip pads 307-1. The first RDL patterns 310-1 may extend from one side of the first chip pad 307-1 toward one corner portion of the first die 300-1. In other words, the first RDL patterns 310-1 extend from the first chip pads 307-1 toward the first connecting pads 340-1. For example, the first RDL patterns 310-1 may be disposed in a line shape with respect to the first connecting pads 340-1 located close to the corner portion of the first die 300-1. In addition, the first RDL patterns 310-1 may have a path bent one or more times toward a corner portion as far from the corner portion of the first die 300-1, as shown in FIG. 2. The first RDL pattern 310-1 may be formed of a conductive material including copper (Cu).

The first die 300-1 may be bonded to the first semiconductor chip 200 so that the first side 305a-1 faces the back-side 210 of the first semiconductor chip 200. In an embodiment, the first die 300-1 is disposed in the second section II of the first semiconductor chip 200.

An end portion of each of the through silicon vias (TSVs) 215 of the first semiconductor chip 200 may overlap the first connecting pad region R2 in which the first connecting pads 340-1 are disposed. Accordingly, the first connecting pads 340-1 of the first die 300-1 are bonded to the back-side bumps 240 of the first semiconductor chip 200 and electrically connected to the through silicon vias (TSVs) 215. At this time, the first die 300-1 and the first semiconductor chip 200 may be bonded through the solder bump 330-1 of the first connecting pad 340-1. The first die 300-1 overlaps the corner portion of the first semiconductor chip 200. Accordingly, a part of the first die 300-1 may protrude beyond the first semiconductor chip 200.

The second die 300-2, the third die 300-3 and the fourth die 300-4 may have substantially the same configuration as the first die 300-1. Accordingly, descriptions of the same elements as the first die 300-1 will be omitted or briefly mentioned, and different configurations will mainly be described.

The second die 300-2 includes a substrate 305-2 having a first side 305a-2 and a second side 305b-2 opposite to the first side 305a-2, second chip pads 307-2, second connecting pads 340-2 gathered at a corner portion of the second die 300-2, and second RDL patterns 310-2 connecting the second chip pads 307-2 to the second connecting pads 340-2, respectively. The second chip pads 307-2, the second connecting pads 340-2, and the second RDL patterns 310-2 are disposed on the first side 305a-2 of the substrate 305-2. Each of the second connecting pads 340-2 includes a first metal bump 325-2 and a second metal bump 330-2 which are stacked sequentially. The first metal bump 325-2 may include copper (Cu) and may have a pillar shape, and the second metal bump 330-2 may include tin-silver (Sn—Ag) alloy.

The second die 300-2 is disposed on the first semiconductor chip 200 so that the first side 305a-2 faces the back-side 210 of the first semiconductor chip 200. In this case, the second die 300-2 is disposed in the first section I of the first semiconductor chip 200. The second connecting pads 340-2 of the second die 300-2 are disposed at a position rotated 90 degrees relative to the center (C) of the first semiconductor chip 200 from the first connection pads 300-1 disposed in the second section II of the first semiconductor chip 200. Each of the second connecting pads 340-1 of the second die 300-2 is bonded to the back side bump 240 of the first semiconductor chip 200 and electrically connected to the through silicon via 215. The second die 300-2 and the first semiconductor chip 200 may be bonded to each other through a second metal bump 330-2 of the second connecting pad 340-2. The second die 300-2 overlaps a corner portion of the first semiconductor chip 200. Accordingly, a part of the second die 300-2 may be disposed to not overlap the first semiconductor chip 200 and to protrude out of the first semiconductor chip 200.

Referring now to FIGS. 2 and 4, the third die 300-3 includes a substrate 305-3 having a first side 305a-3 and a second side 305b-3 opposite to the first side 305a-3, third chip pads 307-3, third connecting pads 340-3 gathered at a corner portion, and third RDL patterns 310-3 connecting the third chip pads 307-3 to the corresponding third connecting pads 340-3, respectively. The third chip pads 307-3, the third connecting pads 340-3 and the third RDL patterns 310-3 may be disposed on the first side 305a-3 of the substrate 305-3. Each of the third connecting pads 340-3 includes a first metal bump 325-3 and a second metal bump 330-3 which are stacked sequentially. The first metal bump 325-3 may include copper (Cu) and may have a pillar shape, and the second metal bump 330-3 may include tin-silver (Sn—Ag) alloy.

The third die 300-3 may be disposed such that the first side 305a-3 faces the back-side 210 of the first semiconductor chip 200. The third die 300-3 is disposed in the fourth section IV of the first semiconductor chip 200. The third connecting pads 340-3 of the third die 300-3 may be disposed at a position rotated 90 degrees relative to the center (C) of the first semiconductor chip 200 of the second connecting pads 300-2 disposed in the second section I, and rotated 180 degrees relative to the center (C) of the first semiconductor chip 200 from the first connecting pads 300-1 disposed in the second section II of the first semiconductor chip 200. The second metal bump 330-3 of the third connecting pad 340-3 of the third die 300-3 is bonded to the back side bump 240 of the first semiconductor chip 200 and electrically connected to the through silicon via (TSV) 215. The third die 300-3 overlaps with a corner portion of the first semiconductor chip 200. Accordingly, a part of the third die 300-3 may be disposed to not overlap with the first semiconductor chip 200 and to protrude from the first semiconductor chip 200.

The fourth die 300-4 includes a substrate 305-4 having a first side 305a-4 and a second side 305b-4 opposite to the first side 305a-4, fourth chip pads 307-4, fourth connecting pads 340-4 gathered at a corner portion, and fourth RDL patterns 310-4. The fourth chip pads 307-4, the fourth connecting pads 340-4 gathered at a corner portion, and the fourth RDL patterns 310-4 may be disposed on the first side 305a-4 of the substrate 305-4. Each of the fourth connecting pads 340-4 includes a first metal bump 325-4 and a second metal bump 330-4 which are stacked sequentially. The first metal bump 325-4 may include copper (Cu) and may have a pillar shape, and the second metal bump 330-4 may include a tin-silver (Sn—Ag) alloy.

The fourth die 300-4 may be disposed such that the first side 305a-4 faces the back-side 210 of the first semiconductor chip 200. The fourth die 300-4 is disposed in the third section III of the first semiconductor chip 200. The fourth connecting pads 340-4 of the fourth die 300-4 may be disposed at a position rotated 90 degrees relative to the center C of the first semiconductor chip 200 from the third connection pads 300-3 disposed in the fourth section IV and rotated 270 degrees relative to the center C of the first semiconductor chip 200 from the first connection pads 300-1 disposed in the second section II of the first semiconductor chip 200. The fourth die 300-4 and the first semiconductor chip 200 may be bonded through the second metal bump 330-4 of the fourth connecting pad 340-4. The fourth die 300-4 is disposed to overlap a corner portion of the first semiconductor chip 200. Accordingly, a part of the fourth die 300-4 may be disposed to not overlap the first semiconductor chip 200 and to protrude out of the first semiconductor chip 200. In other words, some portions of the first to fourth dies 300-1 to 300-4 protrude from the four sides of the first semiconductor chip 200 toward the outside of the first semiconductor chip 200.

Referring now to FIGS. 3 and 4, supporting members 360 are disposed to correspond to portions of the first to fourth dies 300-1 to 300-4 which protrude beyond the first semiconductor chip 200. The supporting members 360 are attached to the package substrate 100 through a first bonding structure 365. The supporting members 360 may be dummy dies or solder resist patterns. The supporting members 360 may be disposed to surround each outer side portion of each corner portion of the first semiconductor chip 200 and to support the first to fourth dies 300-1 to 300-4 from the bottom. The supporting members 360 may be bonded to the first to fourth dies 300-1 to 300-4 through a second bonding structure 370, respectively. The first bonding structure 365 or the second bonding structure 370 may include a dummy bump or an adhesive tape. The supporting member 360 and the first to fourth dies 300-1 to 300-4 are not electrically connected to each other.

The first to fourth dies 300-1 to 300-4 disposed in the four sections I, II, III and IV of the first semiconductor chip 200 are spaced apart from each other by predetermined distances SC1 and SC2. A first connecting pad region, in which the first connecting pads 340-1 of the first die 300-1 are disposed, is disposed to diagonally face a third connecting pad region in which the third connecting pads 340-3 of the third die 300-3 are disposed. A second connecting pad region, in which the second connecting pads 340-2 of the second die 300-2 are disposed, is disposed to diagonally face a fourth connecting pad region in which the fourth connecting pads 340-4 of the fourth die 300-4 are disposed. The first connecting pad region of the first die 300-1 and the second connecting pad region of the second die 300-2 are disposed to be adjacent and to each other in the horizontal direction.

The second die 300-2 may be spaced apart from the first die 300-1 in the horizontal direction. Also, the third connecting pad region of the third die 300-3 and the fourth connecting pad region of the fourth die 300-4 are disposed to be adjacent to each other in the horizontal direction.

Referring now to FIGS. 1, 3 and 4, the exposed portion of the package substrate 100, supporting member 360, the first semiconductor chip 200, and the second semiconductor chip 300 are covered with a molding member 380. The molding member 380 may include an insulation material such as epoxy molding compound (EMC).

The package structure according to an embodiment may be configured as a system in package (SIP). In the SIP, a plurality of semiconductor chips that perform various functions are implemented in a single package. In an embodiment, a plurality of second semiconductor chips 300 are disposed on the first semiconductor chip 200 and the SIP can be implemented. According to the present disclosure, there is an advantage in that a large amount of data can be processed at a time. Also, it is possible to omit the processes of forming the through silicon vias (TSVs) inside the semiconductor chip in order to vertically laminate the second semiconductor chips by electrically connecting the second semiconductor chips 300 to the first semiconductor chip 200 using the RDL patterns. Accordingly, the process costs caused by a number of process steps for forming the through silicon vias (TSVs) can be reduced. In addition, since the second semiconductor chips 300 are disposed on the first semiconductor chip 200 in the horizontal direction instead of laminated vertically, it is possible to implement a thin package.

On the other hand, in an embodiment, though it is described that all four dies, the first to forth dies 300-1, 300-2, 300-3 and 300-4, of the second semiconductor chip 300 are disposed in the four sections I, II, III and IV of the first semiconductor chip 200, but embodiments are not limited thereto. In some embodiments, the second semiconductor chip 300 may be selectively disposed in two sections of the first semiconductor chip 200. For instance, the first die 300-1 may be disposed in the first section I or the second section II of the first semiconductor chip, and the second die 300-2 may be disposed in the third section III diagonally facing the first section I, or in the fourth section IV diagonally facing the second section II. Alternatively, the first die 300-1 may be disposed in the second section II of the first semiconductor chip 200, and the second die 300-2 may be disposed in the first section I adjacent and parallel to the first die 300-1. In addition, the second semiconductor chip 300 may be disposed to overlap a side of the first semiconductor chip 200 instead of being overlapped by a corner portion of the first semiconductor chip 200. This will be described with reference to the drawings.

FIG. 5 is a plan view illustrating a semiconductor package according to another embodiment.

Referring to FIG. 5, the semiconductor package includes a package substrate 400, a first semiconductor chip 500 disposed on the package substrate 400, and second semiconductor chips 600 disposed to be overlapped with two opposite sides of the first semiconductor chip 500. The second semiconductor chips 600 include a first die 600-1 and a second die 600-2. The first semiconductor chip 500 may be disposed below the first die 600-1 and the second die 600-2. The package substrate 400 may include a printed circuit board (PCB). A plurality of substrate pads (not illustrated) for electrically connecting the package substrate 400 to the first semiconductor chip 500 are arranged on a front side 400a of the package substrate 400. The substrate pads may be formed of a conductive material, such as copper (Cu), nickel (Ni) or gold (Au).

The first semiconductor chip 500 is disposed on the front side 400a of the package substrate 400, and the first die 600-1 and the second die 600-2 are disposed on the first semiconductor chip 500. The first semiconductor chip 500 may be electrically connected to first connecting pads 620-1 and second connecting pads 620-2. First chip pads 605-1, first connecting pads 620-1, and first re-distribution layer (RDL) patterns 610-1 electrically connecting the first chip pads 605-1 to the first connecting pads 620-1, are disposed on a surface of the first die 600-1. The first chip pads 605-1 are arranged in a line in a first chip pad region R1 disposed at the center portion of the first die 600-1. Each of the chip pads 605-1 may include copper (Cu) or aluminum (Al). The first connecting pads 620-1 are exclusively disposed in a first connecting pad region R2. The first connecting pad region R2 is spaced apart from the first chip pad region R1 by a predetermined distance and located at one of four corners of the first die 600-1. The first connecting pad 620-1 may include copper (Cu). The first RDL patterns 610-1 connect the first chip pads 605-1 to the first connecting pads 620-1. To this end, the first RDL patterns 610-1 may have a path bent one or more toward a corner portion of the first die 600-1 where the first connecting pads 620-1 are disposed.

Second chip pads 605-2, second connecting pads 620-2, and second RDL patterns 610-2 are disposed on the second die 600-2. The second chip pads 605-2, the second connecting pads 620-2, and the second RDL patterns 610-2 may have the same features as the first chip pads 605-1, the first connecting pads 620-1, and the first RDL patterns 610-1 of the first die 600-1, respectively. The second connecting pads 620-2 may be disposed at a position rotated 180 degrees from the position where the first connecting pads 620-1 are disposed.

A plurality of through silicon vias (TSVs) 510 are disposed in the first semiconductor chip 500. The through silicon vias (TSVs) 510 may be disposed to correspond to the first connecting pads 620-1 gathered at one of the four corners of the first die 600-1. In addition, the through silicon vias (TSVs) 510 may be disposed to correspond to the second connecting pads 620-2 gathered at one of the four corners of the second die 600-2. The through silicon vias (TSVs) 510 may be bonded to the second connecting pads 620-2.

The first die 600-1 and the second die 600-2 may be disposed to overlap with two opposite sides 500a and 500b of the first semiconductor chip 500. Accordingly, portions of the first die 600-1 and the second die 600-2 do not overlap with the first semiconductor chip 500 and may protrude out of the first semiconductor chip 500. Although it is not illustrated, the package substrate 400, the first semiconductor chip 500, and the second semiconductor chips 600 may be covered with a molding material, such as epoxy molding compound (EMC).

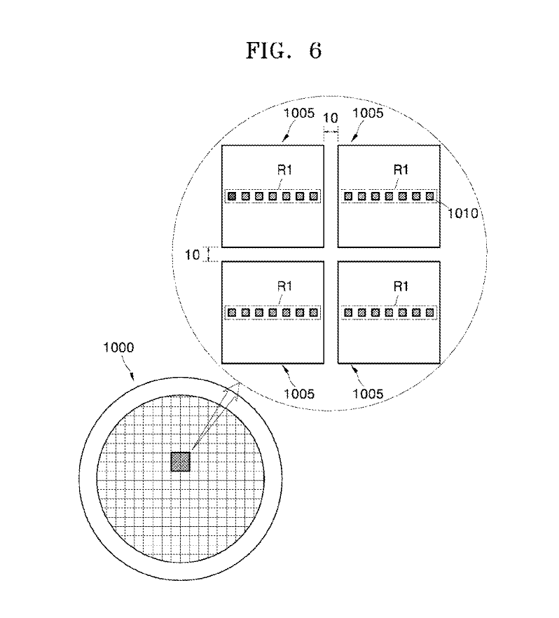

FIGS. 6 to 22 are schematic views illustrating a method for manufacturing a semiconductor package according to an embodiment.

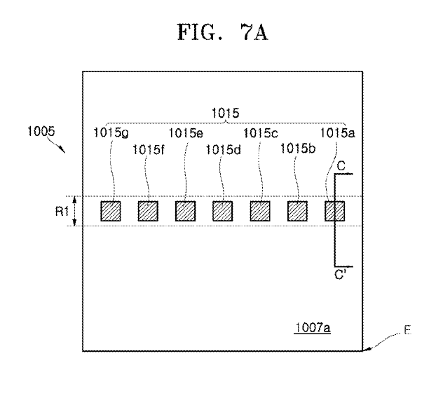

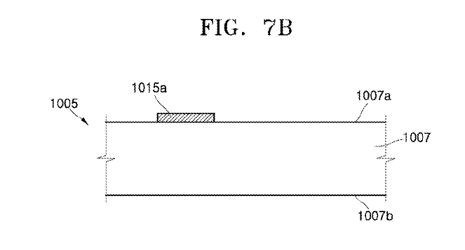

Referring to FIGS. 6 and 7, chip pads 1015 are formed in a chip pad region R1 of dies 1005 disposed on a substrate 1000. Each of the dies 1005 may have square shape and may be spaced apart from each other by interposing a scribe lane 10 on the substrate 1000. The dies 1005 may be semiconductor chips requiring high capacity and high integration. The dies 1005 may also be memory chips in which memory integrated circuits, for example, DRAM, SRAM, FLASH memory, MRAM, ReRAM, FeRAM, or PcRAM are integrated.

FIG. 7a is an enlarged view of one of the dies 1005 in FIG. 6, and FIG. 7b is a cross-sectional view taken along C-C′ direction in FIG. 7a. Referring to FIGS. 6, 7a, and 7b, the chip pad region R1 is disposed on a front side of the die 1005, and chip pads 1015 are arranged in the chip pad region R1. A substrate (or also referred to as a wafer) 1007 of the die 1005 includes a first surface 1007a and a second surface 1007b, and may be formed of silicon (Si). Although it is not illustrated, integrated circuits may be disposed on the substrate 1007. The first surface 1007a of the substrate 1007 may be defined as a side in which active elements or passive elements are formed, that is, the first surface 1007a may be defined as a side where an active region exists, and the second surface 1007b may be defined as a side opposite to the first surface 1007a.

The chip pad region R1 may be located in the center portion of the first surface 1007a of the substrate 1007. A plurality of chip pads 1015 may be formed to be spaced apart from each other and may be arranged in a line in the chip pad region R1. The chip pads 1015 may be arranged in the horizontal direction of the die 1005, which is X-axis direction. In an embodiment, the chip pads 1015 include chip pads 1015a and 1015b disposed near the corner portion E of the die 1005, and chip pads 1015c, 1015d, 1015e, 1015f and 1015g disposed further than the chip pads 1015a and 1015b from the corner portion E of the die 1005. In FIG. 7a, though it is illustrated that the chip pads 1015 are disposed in the center portion of the first surface 1007a, embodiments are not limited thereto. For instance, though it is not illustrated, the chip pads 1015 may be arranged at an edge portion of the first surface 1007a. The chip pads 1015 may include copper (Cu) or aluminum (Al).

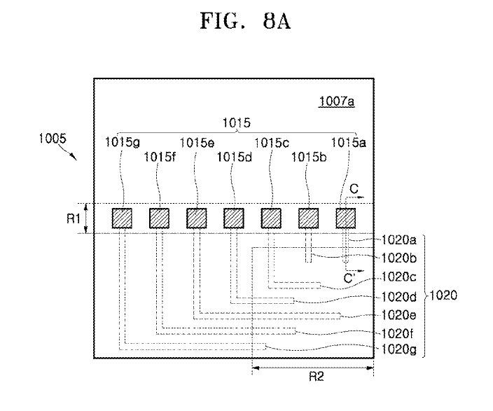

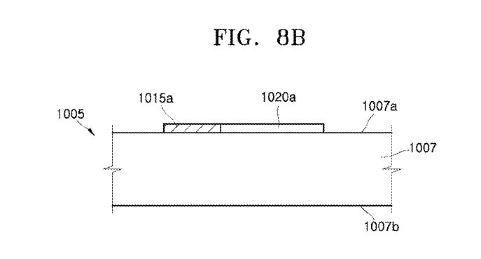

FIG. 8a is an enlarged view of one die 1005 and FIG. 8b is a cross-sectional view taken along C-C′ direction in FIG. 8a. Referring to FIGS. 8a and 8b, redistribution layer (RDL) patterns 1020 are formed on the substrate 1007. The RDL patterns 1020 are formed to contact one side portion of each of the chip pads 1015 on the first surface 1007a of the substrate 1007. The RDL patterns 1020 may be formed to extend toward a corner portion of the square shaped die 1005. The RDL patterns 1020 extend toward a connecting pad region R2 in which the connecting pads are to be formed.

The RDL patterns 1020 may be formed to extend from one side of the chip pads 1015 which contact the RDL patterns 1020. The RDL patterns 1020a, 1020b connected to the chip pads 1015a, 1015b disposed relatively close to a corner portion where the connecting pad region R2 of the die 1005 is located may be formed in a shape of a straight line. The RDL patterns 1020c, 1020d, 1020e, 1020f and 1020g connected to the chip pads 1015c, 1015d, 1015e, 1015f and 1015g which are disposed relatively far from the corner portion of the die 1005 may be formed to have a path bent one or more times toward the corner portion. The RDL patterns 1020 may be formed of a conductive material including copper (Cu) in order to transmit electrical signals.

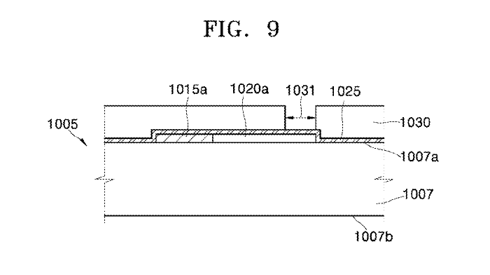

Referring to FIG. 9, a seed metal layer 1025 is formed on the first surface 1007a of the substrate 1007. The seed metal layer 1025 may be formed of copper (Cu) using a chemical vapor deposition (CVD) method or a physical vapor deposition (PVD) method. A mask pattern 1030 including an opening 1031 defining a region in which the connecting pads are to be formed. The opening 1031 of the mask pattern 1030 selectively exposes the seed metal layer 1025 in a region where the connecting pads are to be formed, and the rest of the first surface 1007a is covered with the mask pattern 1030. The opening 1031 may be formed in a circular shape.

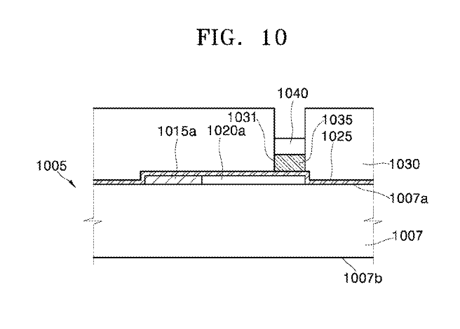

Referring to FIG. 10, a first metal layer 1035 and a second metal layer 1040 are sequentially formed on the seed metal layer 1025 exposed by the opening 1031 of the mask pattern 1030. The first metal layer 1035 or the second metal layer 1040 may be formed using an electroplating process. When performing the electroplating process, a metal layer grows selectively at the exposed portion of the seed metal layer 1025, and the first metal layer 1035 is formed. The first metal layer 1035 may be formed of a conductive material including copper (Cu). The second metal layer 1040 may be formed of a material containing tin-silver (Sn—Ag) alloy.

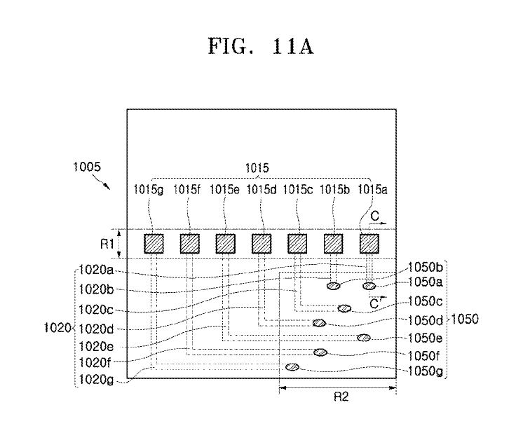

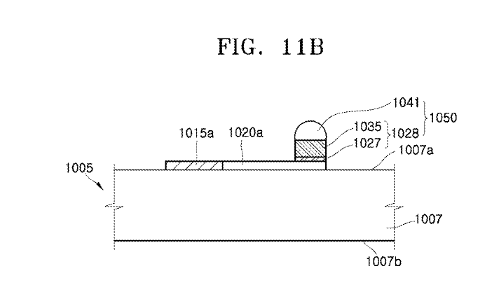

Referring to FIGS. 11a and 11b, the mask pattern (1030 of FIG. 10) is removed by a strip process. Then, the portion of the seed metal layer 1025 which is not covered with the first metal layer 1035 and the second metal layer 1040 is exposed. Then, a seed metal pattern 1027 is formed by performing an etching process to remove the exposed portion of the seed metal layer 1025. In the etching process, the remaining portion except the portion covered with the first metal layer 1035 and the second metal layer 1040 is removed.

Next, a reflow process is performed to the second metal layer 1040 and a second metal bump 1041 of a hemispherical shape is formed. Then, connecting pads 1050 including a stacked first metal bump 1028 and a second metal bump 1041 which are formed of the seed metal pattern 1027 and the first metal layer 1035 are formed. The connecting pads 1050 include connecting pads 1050a and 1050b respectively disposed on the RDL pattern 1020a and 1020b disposed close to a corner portion in which the connecting pad region R2 of the die 1005 is located, and connecting pads 1050c, 1050d, 1050e, 1050f and 1050g respectively disposed on the RDL patterns 1020c, 1020d, 1020e, 1020f and 1020g located far from the corner portion where the connecting pad region R2 of the die 1005 is located.

Referring to FIG. 11a, the chip pads 1015 arranged in the chip pad region R1, the plurality of connecting pads 1050 spaced apart from the chip pad region R1 by a predetermined distance and exclusively disposed in the connecting pad region R2, and the RDL patterns 1020 electrically connecting the chip pads 1015 to the connecting pads 1050 may be disposed on a die 1005.

Next, a singulation process is performed to the scribe lane 10 of the substrate (1000 in FIG. 6), as shown in FIG. 12, and the substrate is separated into individual dies 1005-1, 1005-2, 1005-3 and 1005-4. The singulation process may be performed using scribing method or sawing method. The dies 1005-1, 1005-2, 1005-3 and 1005-4 are defined as a first die 1005-1, a second die 1005-2, a third die 1005-3, and a fourth die 1005-4.

First chip pads 1015-1 disposed on the first die 1005-1 and may be arranged in a line, a plurality of first connecting pads 1050-1 exclusively disposed at a corner portion of the first die 1005-1, and first RDL patterns 1020-1 electrically connecting the first chip pads 1015-1 to the first connecting pads 1050-1 are disposed on the first die 1005-1. Second chip pads 1015-2 disposed on the second die 1005-2 and may be arranged in a line, a plurality of second connecting pads 1050-2 exclusively disposed at a corner portion of the second die 1005-2, and second RDL patterns 1020-2 electrically connecting the second chip pads 1015-2 to the second connecting pads 1050-2 are disposed on the second die 1005-2. Third chip pads 1015-3 disposed on the third die 1005-3, a plurality of third connecting pads 1050-3 disposed exclusively at a corner portion of the third die 1005-3, and third RDL patterns 1020-3 electrically connecting the third chip pads 1015-3 to the third connecting pads 1050-3 are disposed on the third die 1005-3. Fourth chip pads 1015-4 disposed on the fourth die, a plurality of fourth connecting pads 1050-4 disposed exclusively at a corner portion of the fourth die 1005-4, and fourth RDL patterns 1020-4 electrically connecting the fourth chip pads 1015-4 to the fourth connecting pads 1050-4 are disposed on the fourth die 1005-4.

Each of the chip pads 1015-1, 1015-2, 1015-3 and 1015-4, each of the connecting pads 1050-1, 1050-2, 1050-3 and 1050-4 and each of the RDL patterns 1020-1, 1020-2, 1020-3 and 1020-4 which are disposed on the first to fourth dies 1005-1 to 1005-4 may have substantially the same feature.

In this embodiment, though the method for manufacturing the first to fourth dies 1005-1 to 1005-4 using one substrate is described, but it is not limited thereto. The first to fourth dies 1005-1 to 1005-4 may be manufactured using different substrates.

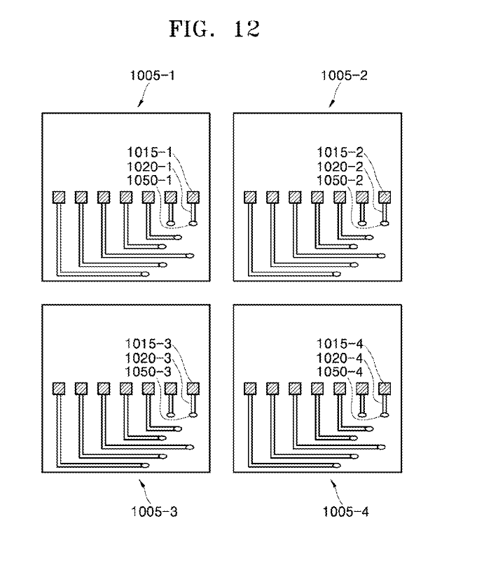

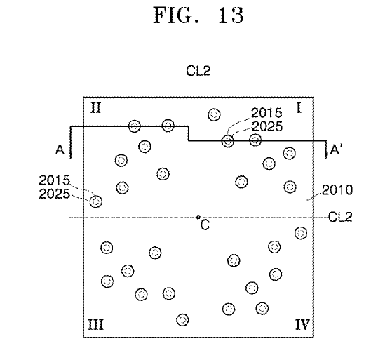

FIG. 13 is a plan view illustrating the step of forming through silicon vias 2015. FIG. 14 is a cross-sectional view taken along A-A′ direction in FIG. 13.

Referring to FIGS. 13 and 14, a first semiconductor chip 2000 is prepared. The first semiconductor chip 2000 includes front side bumps 2035 and back side bumps 2025 which are electrically connected to the through silicon vias 2015. The first semiconductor chip 2000 includes a core portion 2003 having a front side 2005 and a back side 2010 opposite to the front side 2005. The core portion 2003 may be formed of silicon (Si). In an embodiment, the first semiconductor chip 2000 may be a logic chip configured as a system on chip (SoC). The system on chip may include a microprocessor or a controller.

The through silicon vias (TSVs) 2015 are formed in the core portion 2003 of the first semiconductor chip 2000. The through silicon vias (TSVs) 2015 may be formed of a metal filling via holes 2013 penetrating the core portion 2003 from the front side 2005 to the back side 2010. The through silicon via 2015 may be formed by filling the via hole 2013 with a metal, such as copper (Cu), silver (Ag), or tin (Sn). Although it is not illustrated, a barrier layer (not illustrated) may be formed between an inner side wall of the via hole 2013 and the metal. The barrier layer prevents the metal material of the metal from being diffused into the core portion 2003.

Each of the through silicon vias (TSVs) 2015 includes a first end portion 2017 disposed in the front side 2005 direction of the core portion 2003, and a second end portion 2019 disposed at the back side 2010 direction of the core portion 2003. The through silicon vias (TSVs) 2015 are connected to the front side bumps 2035 at the first end portion 2017. Each of the front side bumps 2035 includes a metal pillar 2020 and a solder bump 2030 formed on the metal pillar 2020. The solder bump 2030 may have a hemispherical shape. The metal pillar 2020 may include copper (Cu). The second end portion 2019 of the through silicon via 2015 is connected to the back side bump 2025. The back side bump 2025 may be formed to have a larger diameter than the through silicon via 2015. Accordingly, the bottom surface of the back side bump 2025 may be formed to extend to the back side 2010 of the core portion 2003 of the first semiconductor chip 2000. The back side bump 2025 may include copper (Cu). The top surface of the back side bump 2025 may be covered with nickel (Ni) or gold (Au).

At least two or more through silicon vias (TSVs) 2015 may be disposed in the core portion 2003. The through silicon vias (TSVs) 2015 are spaced apart from each other by a predetermined distance. Referring to FIG. 13, the first semiconductor chip 2000 may be divided into a plurality of planes or sections by central lines CL2 intersecting the first semiconductor chip 2000 in the horizontal and vertical directions. In an embodiment, the first semiconductor chip 2000 may be divided into four sections, as illustrated. The four sections consist of a first section I located in a first quadrant, a second section II located in a second quadrant, a third section III located in a third quadrant, and a fourth section IV located in a fourth quadrant. Each of the first to fourth sections I-IV has a square shape.

The through silicon vias (TSVs) 2015 may be locally distributed in a certain region of the first to fourth sections I-IV. More specifically, the through silicon vias (TSVs) 2015 may be exclusively distributed at a corner portion of each of the first to fourth sections I-IV. In an embodiment, the through silicon vias (TSVs) 2015 may be gathered in the corner portions adjacent to the geometrical center C of the first semiconductor chip 2000. The region where the through silicon vias (TSVs) 2015 are arranged may overlap with the connecting pad region R2 of FIG. 11 of the dies 1005-1, 1005-2, 1005-3 and 1005-4 shown at a later step.

In addition, the through silicon vias (TSVs) 2015 disposed in the first to fourth sections I-IV may be disposed at positions rotated by 90 degrees to 270 degrees from each other. More specifically, the through silicon vias (TSVs) 2015 disposed in the second section II are disposed at a position rotated by 90 degrees from the through silicon vias (TSVs) 2015 disposed in the first section I. Also, the through silicon vias (TSVs) 2015 disposed in the third section III are disposed at a position rotated by 180 degrees from the through silicon vias (TSVs) 2015 disposed in the first section I. In addition, the through silicon vias (TSVs) 2015 disposed in the fourth section IV are disposed at a position rotated by 270 degrees from the through silicon vias (TSVs) 2015 disposed in the first section I.

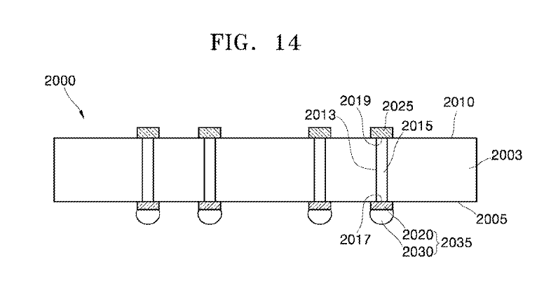

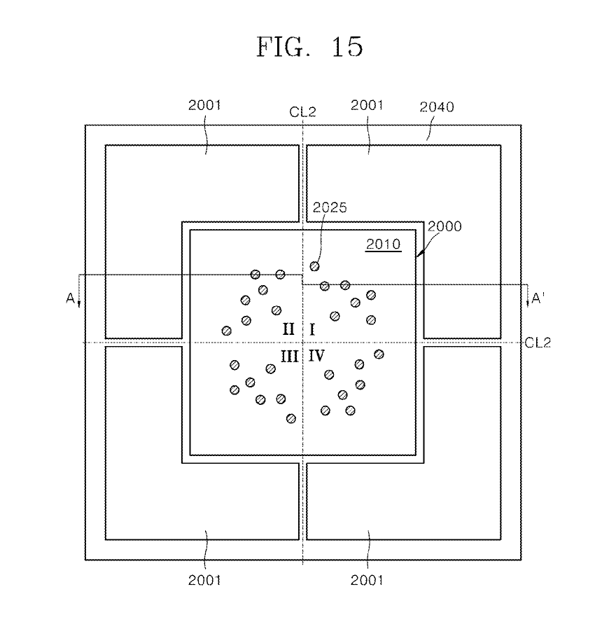

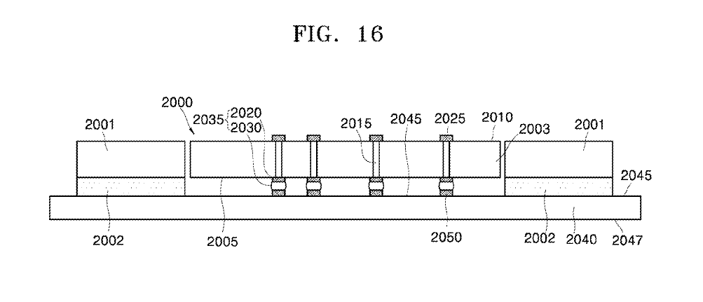

FIG. 16 is a cross-sectional view taken along A-A′ direction in FIG. 15. Referring to FIGS. 15 and 16, the first semiconductor chip 2000 including the through silicon vias (TSVs) 2015 is mounted on a package substrate 2040. The package substrate 2040 may include a printed circuit board (PCB) and may be a member capable of mounting a semiconductor chip. The package substrate 2040 includes a front side 2045 and a back side 2047 opposite to the front side 2045. Circuit wiring patterns (not illustrated) may be disposed on the package substrate 2040.

A plurality of substrate pads 2050 electrically connecting the package substrate 2040 to the first semiconductor chip 2000 may be disposed on the front side 2045 of the package substrate 2040. The substrate pads 2050 may transmit electrical signals to the back side 2047 of the package substrate 2040 through the circuit wiring patterns (not illustrated) disposed in the package substrate 2040. The substrate pads 2050 may include copper (Cu), nickel (Ni), or gold (Au). The substrate pads 2050 may be arranged at the same locations as the feature arrangement of the through silicon vias (TSVs) 2015.

In order to mount the first semiconductor chip 2000 on the package substrate 2040, the first semiconductor chip 2000 is disposed so that the front side 2005 of the first semiconductor chip 2000 faces the front side 2045 of the package substrate 2040. The front side bumps 2035 of the first semiconductor chip 2000 are bonded to the substrate pads 2050 of the package substrate 2040. Then, as illustrated in FIG. 15, which is a plan view of FIG. 16, the back side bumps 2025 of the first semiconductor chip 2000 are exposed to the outside. The first semiconductor chip 2000 may be disposed in the center portion of the package substrate 2040, but it is not limited thereto.

Then, a supporting member 2001 is disposed on the package substrate 2040 except for the region where the first semiconductor chip 2000 is disposed. The supporting member 2001 may have a shape surrounding the outer side of the four corners of the first semiconductor chip 2000. The supporting member 2001 may have a shape of “┐” or “└”. The supporting member 2001 may include a dummy die or a solder resist pattern. The supporting member 2001 may be attached on the package substrate 2040 via a first bonding structure 2002. The first bonding structure 2002 may include a dummy bump or an adhesive.

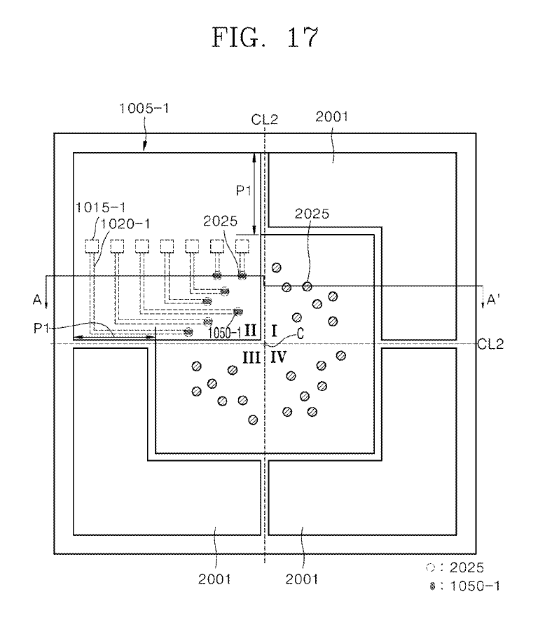

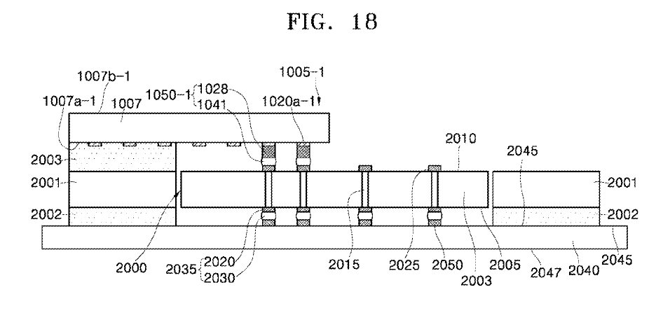

Referring to FIGS. 17 and 18, the first die 1005-1 is attached to the first semiconductor chip 2000. To this end, the first die 1005-1 is disposed on the second section II of the first semiconductor chip 2000. The first die 1005-1 may be disposed at a position spaced apart from the central lines CL2 which intersect the first semiconductor chip 2000 in the horizontal and vertical directions by a predetermined distance. The first die 1005-1 is disposed so that the first surface 1007a-1 faces the back side 2010 of the first semiconductor chip 2000. In this case, the first connecting pads 1050-1 may be exclusively arranged in the connecting pad region disposed at a corner portion of the first die 1005-1. The connecting pad region may be located at a position adjacent to the center portion C of the first semiconductor chip 2000. Accordingly, the first connecting pads 1050-1 of the first die 1005-1 are disposed to face the back side bumps 2025 of the first semiconductor chip 2000.

The first die 1005-1 is attached to the first semiconductor chip 2000. Then, the first die 1005-1 may be electrically connected to the through silicon vias (TSVs) 2015 through the back side bumps 2025. The first die 1005-1 overlaps the first semiconductor chip 2000 only in the second section II. Accordingly, a part of the first die 1005-1 does not overlap the first semiconductor chip 2000 and may protrude outside the first semiconductor chip 2000 by a first distance P1.

The part of the first die 1005-1, which protrudes outward from the first semiconductor chip 2000, is supported by the supporting member 2001. The first die 1005-1 and the supporting member 2001 may be bonded to each other via a second adhesion structure 2003. The second adhesion structure 2003 may include a dummy bump or an adhesive.

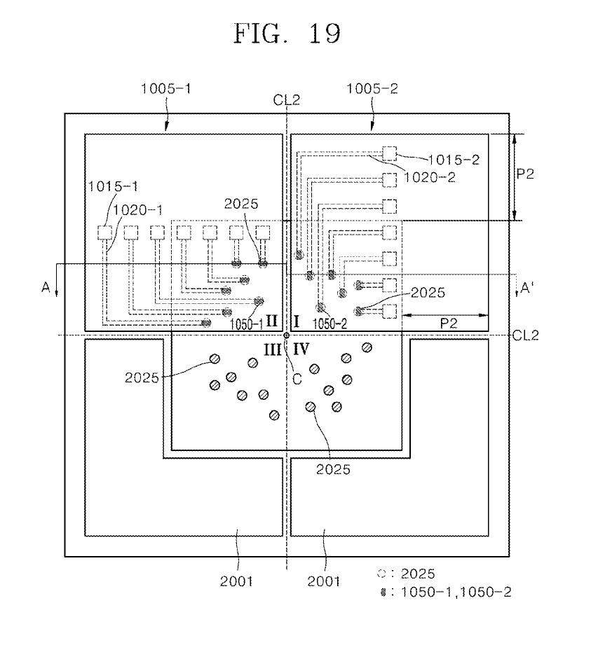

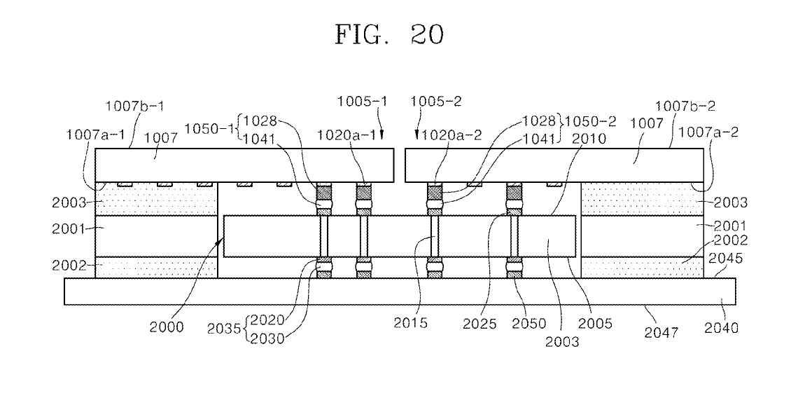

Referring to FIGS. 19 and 20, the second die 1005-2 is attached to the first semiconductor chip 2000. The second die 1005-2 may be disposed at a position spaced apart from the central lines CL2 intersecting the first semiconductor chip 2000 in the horizontal and vertical directions by a predetermined distance. The second die 1005-2 is disposed so that the first surface 1007a-2 faces the back side 2010 of the first semiconductor chip 2000. The second connecting pads 1050-2 are exclusively disposed in the connecting pad region disposed at a corner portion of the second die 1005-2. Accordingly, the second connecting pads 1050-2 of the second die 1005-2 face the back side bumps 2025 of the first semiconductor chip 2000.

The second die 1005-2 is disposed in the first section I of the first semiconductor chip 2000 in a state that is rotated by 90 degrees relative to the center C of the first semiconductor chip 2000 from the first die 1005-1. Then, the second connecting pads 1050-2 may be disposed at a position rotated by 90 degrees relative to the center C of the first semiconductor chip 2000 from the first connecting pads 1050-1, and the second connecting pads 1050-2 may be disposed to correspond to the through silicon vias 2015 disposed in the first section I. Then, the second die 1005-2 is attached to the first semiconductor chip 2000. Then, the second die 1005-2 may be electrically connected to the through silicon vias (TSVs) 2015 through the back side bump 2025.

The second die 1005-2 overlaps the first semiconductor chip 2000 only in the first section I. Accordingly, a part of the second die 1005-2 does not overlap the first semiconductor chip 2000 and may protrude outside the first semiconductor chip 2000 by a second distance P2. The part of the second die 1005-2, which protrudes outside the first semiconductor chip 2000, is supported by the supporting member 2001. The second die 1005-2 and the supporting member 2001 may be bonded to each other via the second adhesion structure 2003. The second adhesion structure 2003 may include a dummy bump or an adhesive.

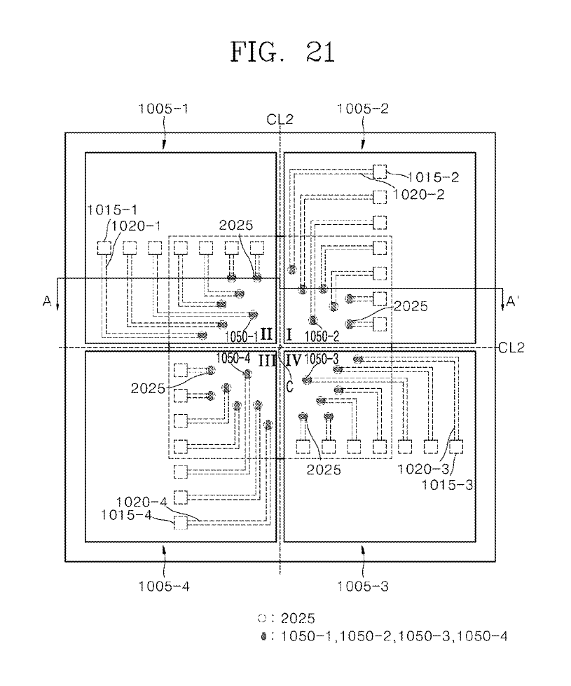

Referring to FIG. 21, the third die 1005-3 is attached to the first semiconductor chip 2000. The third die 1005-3 is disposed in the fourth section IV of the first semiconductor chip 2000. The third die 1005-3 may be disposed at a position spaced apart from the central lines CL2 intersecting the first semiconductor chip 2000 in the horizontal and vertical directions by a predetermined distance. The third die 1005-3 is disposed so that the first surface faces the back side 2010 of the first semiconductor chip 2000. The third connecting pads 1050-3 are exclusively disposed at a corner portion of the third die 1005-3. Accordingly, the third connecting pads 1050-3 of the third die 1005-3 face the back side bumps 2025 of the first semiconductor chip 2000.

The third die 1005-3 is disposed in the fourth section IV of the first semiconductor chip 2000 in a state that is rotated by 90 degrees relative to the center C of the first semiconductor chip 2000 from the second die 1005-2 disposed in the first section I. Then, the third connecting pads 1050-3 may be disposed at a position rotated by 90 degrees from the second connecting pads 1050-2 disposed in the first section I, and rotated 180 degrees from the first connecting pads 1050-1 disposed in the second section II relative to the center C of the first semiconductor chip 2000. And, the third connecting pads 1050-3 may be disposed to correspond to the through silicon vias (TSVs) 2015 disposed in the fourth section IV. Then, the third die 1005-3 is attached to the first semiconductor chip 2000. Then, the third die 1005-3 may be electrically connected to the through silicon vias (TSVs) 2015 through the back side bump 2025.

The third die 1005-3 overlaps the first semiconductor chip 2000 only in the fourth section IV. Accordingly, a part of the third die 1005-3 does not overlap with the first semiconductor chip 2000 and may be protrude outside the first semiconductor chip 2000. The part of the third die 1005-3 protrudes outward from the first semiconductor chip 2000 supported by the supporting member 2001 of FIG. 19. The third die 1005-3 and the supporting member 2001 may be bonded to each other via the second adhesion structure (2003 of FIG. 20). The second adhesion structure 2003 may include a dummy bump or an adhesive.

Next, the fourth die 1005-4 is attached to the first semiconductor chip 2000. The fourth die 1005-4 is disposed in the third section III of the first semiconductor chip 2000. The fourth die 1005-4 may be disposed at a position spaced apart from the central lines CL2 intersecting the first semiconductor chip 2000 in the horizontal and vertical directions by a predetermined distance. The fourth die 1005-4 is disposed so that the first surface faces the back side 2010 of the first semiconductor chip 2000. The fourth connecting pads 1050-4 are exclusively disposed in the connecting pad region disposed at a corner portion of the fourth die 1005-4. Accordingly, the fourth connecting pads 1050-4 of the fourth die 1005-4 face the back side bumps 2025 of the first semiconductor chip 2000.

The fourth die 1005-4 is disposed in the third section III of the first semiconductor chip 2000 in a state that is rotated by 90 degrees from the third die 1005-3 and rotated by 270 degrees from the first die 1005-1 relative to the center C of the first semiconductor chip 2000. Then, the fourth die 1005-4 is disposed to correspond to the through silicon vias (TSVs) 2015 disposed in the third section III. Then, the fourth die 1005-4 is attached to the first semiconductor chip 2000. Then, the fourth die 1005-4 may be electrically connected to the through silicon vias (TSVs) 2015 through the back side bumps 2025.

The fourth die 1005-4 overlaps the first semiconductor chip 2000 only in the third section III. Accordingly, a part of the fourth die 1005-4 does not overlap with the first semiconductor chip 2000 and may protrude outside the first semiconductor chip 2000. The part of the fourth die 1005-4 protruding outward from the first semiconductor chip 2000 is supported by the supporting member (2001 of FIG. 19), which is disposed in the third section III. The fourth die 1005-4 and the supporting member 2001 may be bonded to each other via the second adhesion structure (2003 of FIG. 20). The second adhesion structure 2003 may include a dummy bump or an adhesive.

The first to fourth dies 1005-1 to 1005-4 that are disposed in the four sections I, II, III and IV of the first semiconductor chip 2000 are spaced apart from each other by a predetermined distance d1. Also, the first connecting pad region where the first connecting pads 1050-1 of the first die 1005-1 are disposed and the third connecting pad region where the third connecting pads 1050-3 of the third die 1005-3 are disposed may be disposed to face each other in a diagonal direction. In addition, the second connecting pad region where the second connecting pads 1050-2 of the second die 1005-2 are disposed and the fourth connecting pad region where the fourth connecting pads 1050-4 of the fourth die 1005-4 are disposed may be disposed to face each other in a diagonal direction. Further, the second connecting pad region may be adjacent to the first connecting pad region in a horizontal direction.

In the embodiment, although it is described that the dies are disposed in all of the four sections I, II, III and IV of the first semiconductor chip 2000, embodiments are not limited thereto. For example, only two dies may be selectively disposed on the first semiconductor chip 2000.

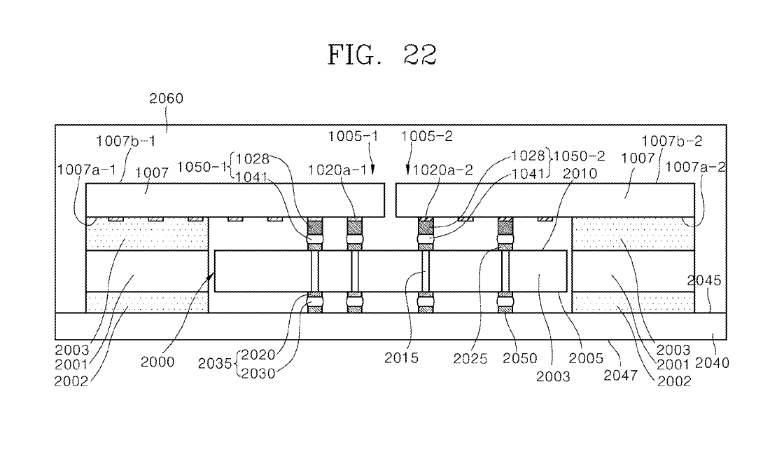

Referring to FIG. 22, a molding member 2060 is formed on the package substrate 2040. The molding member 2060 covers the exposed region of the package substrate 2040, which is the first semiconductor chip 2000 and the dies 1005-1 to 1005-4. The molding member 2060 may be formed by using an insulation coating material, such as an epoxy molding compound (EMC).

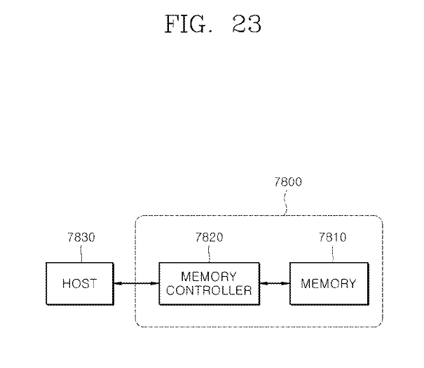

The semiconductor package described above may be applied to various electronic systems. FIG. 23 is a block diagram illustrating a representation of an example of an electronic system including a memory card 7800 including at least one semiconductor package according to an embodiment.

Referring to FIG. 23, the memory card 7800 includes a memory or memory component 7810, such as a nonvolatile memory device, and a memory controller 7820. The memory 7810 and the memory controller 7820 may store data or read stored data. The memory 7810 and/or the memory controller 7820 include one or more semiconductor chips disposed in an embedded package according to an embodiment. The memory 7810 may include a nonvolatile memory device to which the technology of the embodiments of the present application is applied. The memory controller 7820 may control the memory 7810 such that stored data is read out or data is stored in response to a read/write request from a host 7830.

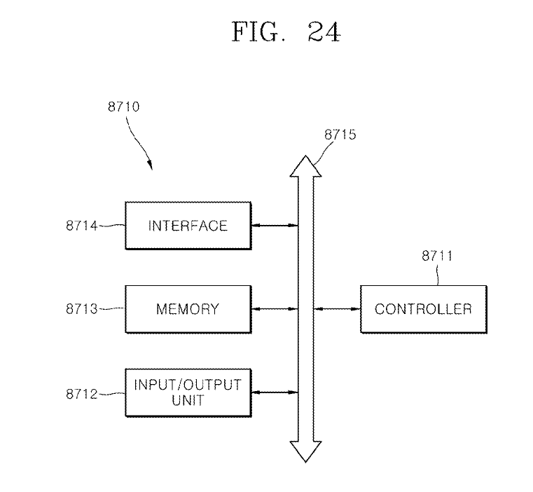

FIG. 24 is a block diagram illustrating a representation of an example of an electronic system 8710 including at least one package according to an embodiment. The electronic system 8710 may include a controller 8711, an input/output unit 8712, and a memory or memory card 8713. The controller 8711, the input/output unit 8712, and the memory 8713 may be coupled with one another through a bus 8715 providing a path through which data may move.

In an embodiment, the controller 8711 may include one or more microprocessors, digital signal processors, microcontrollers, and/or logic devices capable of performing the same functions as these components. The controller 8711 or the memory 8713 may include one or more semiconductor packages according to embodiments of the present disclosure. The input/output device 8712 may include at least one selected from among a keypad, a keyboard, a display device, a touchscreen and so forth. The memory 8713 is a device for storing data.

The memory 8713 may store data and/or commands to be executed by the controller 8711, and the like. The memory 8713 may include a volatile memory device such as a DRAM and/or a nonvolatile memory device such as a flash memory. For example, a flash memory may be mounted to an information processing system such as a mobile terminal or a desktop computer. The flash memory may constitute a solid state disk (SSD). In this example, the electronic system 8710 may stably store a large amount of data in a flash memory system.

The electronic system 8710 may further include an interface 8714 configured to transmit and receive data to and from a communication network. The interface 8714 may be a wired or wireless type. For example, the interface 8714 may include an antenna or a wired or wireless transceiver.

The electronic system 8710 may be realized as a mobile system, a personal computer, an industrial computer, or a logic system performing various functions. For example, the mobile system may be any one of a personal digital assistant (PDA), a portable computer, a tablet computer, a mobile phone, a smart phone, a wireless phone, a laptop computer, a memory card, a digital music system, and an information transmission/reception system.

If the electronic system 8710 is equipment capable of performing wireless communication, the electronic system 8710 may be used in a communication system such as of CDMA (code division multiple access), GSM (global system for mobile communications), NADC (north American digital cellular), E-TDMA (enhanced-time division multiple access), WCDAM (wideband code division multiple access), CDMA2000, LTE (long term evolution) and Wibro (wireless broadband Internet).

Embodiments of the present disclosure have been disclosed for illustrative purposes. Those skilled in the art will appreciate that various modifications, additions and substitutions are possible, without departing from the scope and spirit of the present disclosure and the accompanying claims.

What is claimed is:

1. A semiconductor package comprising:
a first die including first chip pads disposed in a first chip pad region on a chip, first connecting pads disposed in a first connecting pad region located at a corner portion of the first die and spaced apart from the first chip pad region by a predetermined distance, and first redistribution layer patterns connecting the first chip pads to the first connecting pads;
a second die including second chip pads disposed in a second chip pad region on the chip and spaced apart from the first die in a horizontal direction, second connecting pads disposed in a second connecting pad region located at a corner portion of the second die and spaced apart from the second chip pad region by a predetermined distance, and second redistribution layer patterns connecting the second chip pads to the second connecting pads, the second connecting pad region is disposed to be adjacent to the first connecting pad region of the first die in the horizontal direction;
a third die including third chip pads disposed in a third chip pad region on the chip and spaced apart from the second die by a predetermined distance in the horizontal direction, third connecting pads disposed in a third connecting pad region located at a corner portion of the third die and spaced apart from the third chip pad region by a predetermined distance, and third redistribution layer patterns connecting the third chip pads to the third connecting pads, the third connecting pad region is disposed to face the first connecting pad region of the first die in the diagonal direction;
a fourth die including fourth chip pads disposed in a fourth chip pad region on the chip and spaced apart from the third die by a predetermined distance in the horizontal direction, fourth connecting pads disposed in a fourth connecting pad region located at a corner portion of the fourth die and spaced apart from the fourth chip pad region by a predetermined distance, and fourth redistribution layer patterns connecting the fourth chip pads to the fourth connecting pads, the fourth connecting pad region is disposed to face the second connecting pad region of the second die in the diagonal direction; and
a first semiconductor chip disposed below the first to fourth dies and electrically connected to the first to fourth dies at a portion overlapped with the first to fourth connecting pad regions, respectively.

2. The semiconductor package of claim 1, wherein each corner portion of the first to fourth dies overlaps a corner portion of the first semiconductor chip.

3. The semiconductor package of claim 1, wherein the first semiconductor chip further comprises through silicon vias disposed at a portion overlapped with the first to fourth connecting pad regions.

4. The semiconductor package of claim 1, wherein the first semiconductor chip comprises four sections divided by central lines intersecting the first semiconductor chip in the horizontal and vertical directions,
wherein the four sections consist of a first section located in a first quadrant, a second section located in a second quadrant, a third section located in a third quadrant, and a fourth section located in a fourth quadrant, and
wherein the first to fourth dies are disposed in the first to fourth sections, respectively.

5. The semiconductor package of claim 4, wherein the first die overlaps the second section of the first semiconductor chip,
wherein the second die overlaps the first section of the first semiconductor chip, and the second connecting pad region of the second die is disposed at a position rotated by 90 degrees from a position where the first connecting pad region of the first die is disposed relative to the center of the first semiconductor chip,
wherein the third die overlaps the fourth section of the first semiconductor chip, and the third connecting pad region of the third die is disposed at a position rotated by 90 degrees from a position where the second connecting pad region of the second die is disposed relative to the center of the first semiconductor chip, and
wherein the fourth die overlaps the third section of the first semiconductor chip, and the fourth connecting pad region of the fourth die is disposed at a position rotated by 90 degrees from a position where the third connecting pad region of the third die is disposed relative to the center of the first semiconductor chip.

6. The semiconductor package of claim 1, wherein the chip pads, the connecting pads, and the redistribution layer patterns disposed on the first to fourth dies have the same features.

7. The semiconductor package of claim 1, wherein the first to fourth chip pad regions are disposed at the center portions or edge portions of the first to fourth dies, respectively.

8. The semiconductor package of claim 1, wherein the first to fourth redistribution layer patterns extend from each one side of the first to fourth chip pads and are connected to the first to fourth connecting pads.

9. The semiconductor package of claim 8, wherein the first to fourth redistribution layer patterns are connected to the connecting pads disposed close to the corner portion of the dies in a straight line shape, and at least some of the first to fourth redistribution layer patterns are connected to be bent to the connecting pads gathered at the corner portions of each die at least one time as far from those corner portions of each dies.

10. The semiconductor package of claim 1, wherein the corner portions of the first to fourth dies are overlapped with four corner portions of the first semiconductor chip.

11. The semiconductor package of claim 1, wherein parts of the first to fourth dies protrude outside the first semiconductor chip.

12. The semiconductor package of claim 1, further comprising:
a package substrate disposed below the first semiconductor chip and including substrate pads electrically connected to the first semiconductor chip;
a supporting member disposed on the package substrate and supporting the first to fourth dies, the supporting member surrounds each outer corner portions of the first semiconductor chip; and
a molding member covering the package substrate, the first semiconductor chip, the supporting member and the first die to the fourth die.

13. The semiconductor package of claim 12, wherein the package substrate further comprises a supporting member disposed on the package substrate, wherein the supporting member surrounds the outer side portions of each corner portions of the first semiconductor chip and supports the first die to the fourth die.

14. The semiconductor package of claim 13, wherein the supporting member includes a dummy die or a solder resist pattern.

15. The semiconductor package of claim 1, wherein the first semiconductor chip is a logic chip including a microprocessor or a controller, and
wherein the first die to the fourth die comprise memory chips performing the same functions.
